(19) United States
(12) Patent Application Publication
(10) Pub. No.: US 2018/0278816 A1
(43) Pub. Date: Sep. 27, 2018

(54) IMAGE PICKUP MODULE, ENDOSCOPE, AND METHOD FOR MANUFACTURING IMAGE PICKUP MODULE

(71) Applicant: OLYMPUS CORPORATION, Tokyo (JP)

(72) Inventor: Jumpei YONEYAMA, Kamiina-gun (JP)

(73) Assignee: OLYMPUS CORPORATION, Tokyo (JP)

(21) Appl. No.: 15/885,886

(22) Filed: Feb. 1, 2018

(30) Foreign Application Priority Data
Mar. 22, 2017 (JP) 2017-056321

(51) Int. Cl. H04N 5/225; G02B 13/00; G02B 23/24; H01L 27/146

(52) U.S. Cl. CPC H04N 5/2254; G02B 13/0085; H04N 5/2253; H01L 24/14; H01L 27/14623; H04N 2005/2255; H01L 27/14636; G02B 23/2484

(57) ABSTRACT

An image pickup module includes an image pickup device including a light receiving section and an external electrode on a light receiving surface on which an image pickup optical system including an optical axis forms an object image, and a cover glass including a first main surface and a second main surface, the second main surface being made to adhere to the light receiving surface via resin, and covering the light receiving section and not covering the external electrode, in which in the cover glass, the second main surface is smaller than the first main surface, and the resin sticks out into a space formed by extending the first main surface in a direction toward the second main surface on the optical axis, to form a fillet between the image pickup device and the cover glass.

### CROSS REFERENCE TO RELATED APPLICATION

This application claims the benefit of Japanese Applications No. 2017-056321 filed in Japan on Mar. 22, 2017, the entire contents of each of which are incorporated herein by their reference.

### BACKGROUND OF INVENTION

### 1. Field of the Invention

The present invention relates to an image pickup module in which an optical member is made to adhere to a light receiving surface of an image pickup device via resin, an endoscope including the image pickup module in which the optical member is made to adhere to the light receiving surface of the image pickup device via the resin, and a method for manufacturing the image pickup module in which the optical member is made to adhere to the light receiving surface of the image pickup device via the resin.

### 2. Description of the Related Art

The image pickup module is disposed in a distal end portion of an electronic endoscope, for example, when used. It is an important issue for low invasion that the endoscope is reduced in diameter, and downsizing of the image pickup module is required.

First, an image pickup module of a wafer level packaging (WLP) type will be simply described. The WLP-type image pickup module is manufactured by cutting and dividing a bonding wafer obtained by bonding an image pickup wafer including a plurality of image pickup devices and a glass wafer to each other into pieces. Accordingly, an entire light receiving surface on which a light receiving section of the image pickup device is formed is covered with a cover glass. The light receiving section in the image pickup device is connected to an external electrode on a rear surface opposing the light receiving surface via a through wiring.

On the other hand, Japanese Patent Application Laid-Open Publication No. 2008-118568 discloses an image pickup module in which a cover glass covering a light receiving section does not cover external electrodes lined up on a light receiving surface. In the image pickup module, a through wiring need not be formed, unlike in the WLP-type image pickup module.

To make the cover glass adhere to an image pickup device, ultraviolet curable resin, for example, is used. That is, after liquid uncured resin is disposed on an adhesive surface, the cover glass and the image pickup device are spaced at a predetermined distance apart from each other, and are subjected to curing processing.

Note that Japanese Patent Application Laid-Open Publication No. 2004-221541 discloses a cover glass for a solid-state image pickup device a side surface of which is inclined. The side surface is inclined to prevent a microcrack. The angle of inclination may be an angle directed inward toward the side surface or an angle directed outward.

### SUMMARY OF THE INVENTION

According to an embodiment of the present invention, there is provided an image pickup module including an image pickup device including a light receiving section and an external electrode on a light receiving surface on which an image pickup optical system including an optical axis forms an object image, and an optical member including a first main surface and a second main surface opposing the first main surface, the second main surface being made to adhere to the light receiving surface via resin, and covering the light receiving section and not covering the external electrode, in which in the optical member, the second main surface is smaller than the first main surface, and the resin sticks out into a space formed by extending the first main surface in a direction toward the second main surface on the optical axis, to form a fillet between the image pickup device and the optical member.

According to another embodiment of the present invention, there is provided an endoscope including an image pickup module, the image pickup module including an image pickup device including a light receiving section and an external electrode on a light receiving surface on which an image pickup optical system including an optical axis forms an object image, and an optical member including a first main surface and a second main surface opposing the first main surface, the second main surface being made to adhere to the light receiving surface via resin, and covering the light receiving section and not covering the external electrode, in which in the optical member, the second main surface is smaller than the first main surface, and the resin sticks out into a space formed by extending the first main surface in a direction toward the second main surface on the optical axis, to form a fillet between the image pickup device and the optical member.

According to still another embodiment of the present invention, there is provided a method for manufacturing an image pickup module, the method including a step of manufacturing an image pickup device including a light receiving section and an external electrode on a light receiving surface on which an image pickup optical system including an optical axis forms an object image, a step of manufacturing an optical member including a first main surface and a second main surface opposing the first main surface by processing the optical member such that the second main surface is smaller than the first main surface, a step of disposing uncured resin between the light receiving surface of the image pickup device and the second main surface of the optical member, a step of making the second main surface adhere to the light receiving surface in such a manner that the optical member covers the light receiving section and does not cover the external electrode and the light receiving surface and the second main surface are spaced apart from each other at a predetermined distance, so as to cause the excessive resin to stick out into a space formed by extending the first main surface in a direction toward the second main surface on the optical axis to form a fillet between the image pickup device and the optical member, and a step of curing the resin.

### BRIEF DESCRIPTION OF THE DRAWINGS

FIG. 1 is a perspective view of an image pickup module according to a first embodiment;

FIG. 2A is a top view of the image pickup module according to the first embodiment;

FIG. 2B is a cross-sectional view along a line IIB-IIB illustrated in FIG. 2A of the image pickup module according to the first embodiment;

FIG. 3 is a flowchart of a method for manufacturing the image pickup module according to the first embodiment;

FIG. 4 is a cross-sectional view for illustrating the method for manufacturing the image pickup module according to the first embodiment;

FIG. 5 is a cross-sectional view of an image pickup module according to a modification 1 to the first embodiment;

FIG. 6 is a cross-sectional view of an image pickup module according to a modification 2 to the first embodiment;

FIG. 7 is a cross-sectional view of an image pickup module according to a modification 3 to the first embodiment;

FIG. 8 is a cross-sectional view of an image pickup module according to a modification 4 to the first embodiment;

FIG. 9 is an exploded perspective view of an image pickup module according to a modification 5 to the first embodiment;

FIG. 10 is an exploded perspective view of an image pickup module according to a modification 6 to the first embodiment;

FIG. 11 is an exploded perspective view of an image pickup module according to a modification 7 to the first embodiment;

FIG. 12 is a perspective view of an image pickup module according to a modification 8 to the first embodiment;

FIG. 13 is a perspective view of an image pickup module according to a second embodiment;

FIG. 14 is a cross-sectional view of the image pickup module according to the second embodiment; and

FIG. 15 is a perspective view of an endoscope according to a third embodiment.

### DETAILED DESCRIPTION OF THE PREFERRED EMBODIMENTS

### First Embodiment

### <Configuration of Image Pickup Module>

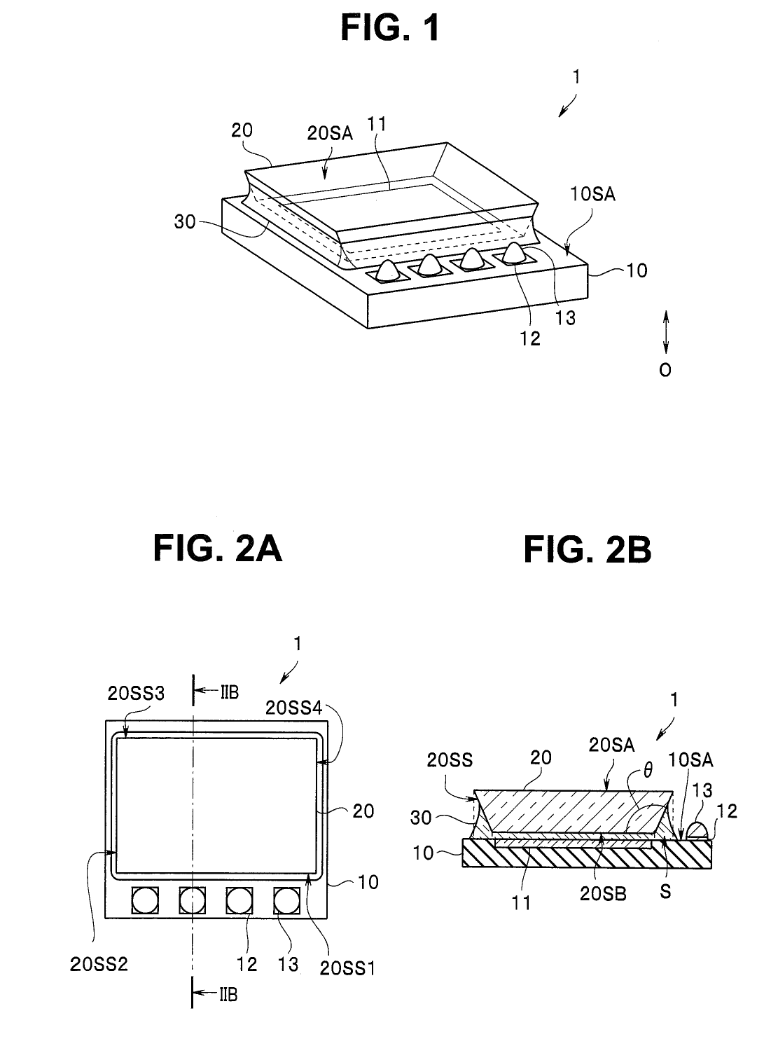

An image pickup module 1 according to the present embodiment includes an image pickup device 10, a cover glass 20 serving as an optical member, and resin 30 via which the image pickup device 10 and the cover glass 20 are made to adhere to each other, as illustrated in FIG. 1, FIG. 2A, and FIG. 2B.

It should be noted that all the drawings are schematic, and a relationship between a thickness and a width of each of sections, a ratio of respective thicknesses of the sections, and the like differ from actual ones. The drawings may respectively include sections which differ in dimensional relationship and ratio. Illustration of some components may be omitted.

The image pickup device 10 including a light receiving surface 10SA on which a light receiving section 11 is formed, on which an image pickup optical system (not illustrated) including an optical axis forms an object image, is a semiconductor device having a rectangular parallelepiped cross section in a direction perpendicular to the optical axis. The image pickup device 10 having a thickness of 100 μm, for example, is manufactured by cutting an image pickup wafer including a plurality of image pickup devices 10. The optical axis is an axis substantially perpendicular to the light receiving section 11 nearly at the center of the light receiving section 11, which is not illustrated.

A plurality of external electrodes 12 connected to the light receiving section 11 are lined up parallel to a side surface 20SS1 around the light receiving section 11 on the light receiving surface 10SA in the image pickup device 10. A bump 13 is disposed on each of the external electrodes 12.

A cover glass 20, which is rectangular in a planar view, includes a first main surface 20SA and a second main surface 20SB opposing the first main surface 20SA. The second main surface 20SB in the cover glass 20 is made to adhere to the light receiving surface 10SA via the transparent resin 30. On the other hand, the light receiving surface 10SA is 2.0 mm in width and 1.8 mm in length (an area: 3.6 mm²), for example. The first main surface 20SA is 1.5 mm in width and 1.5 mm in length (an area: 2.25 mm²) and is 400 μm in thickness, for example, such that the cover glass 20 falls within a projection plane in a direction toward an optical axis (O) of the image pickup device 10 and does not cover the external electrodes 12.

The cover glass 20, which protects the light receiving section 11, is accurately positioned to completely cover the light receiving surface 10SA and not to cover the external electrodes 12, and is made to adhere to the light receiving section 11 via the resin 30. Note that an optical member may be a transparent resin plate.

Ultraviolet curable resin 30 is subjected to curing processing by ultraviolet irradiation from the first main surface 20SA in the cover glass 20.

In the image pickup module 1 according to the present embodiment, a side surface 20SS (20SS1 to 20SS4) of the cover glass 20 is inclined. Therefore, the second main surface 20SB is smaller than the first main surface 20SA. That is, an angle of inclination θ of the side surface 20SS (see FIG. 2B) is an obtuse angle. The resin 30 sticks out of an adhesive surface into a space S formed by extending the first main surface 20SA in the direction toward the optical axis (O), i.e., a direction toward the second main surface 20SB, to form a fillet between the image pickup device 10 and the cover glass 20. The fillet refers to a portion where the resin 30, which has stuck out, expands in a skirt shape from the adhesive surface.

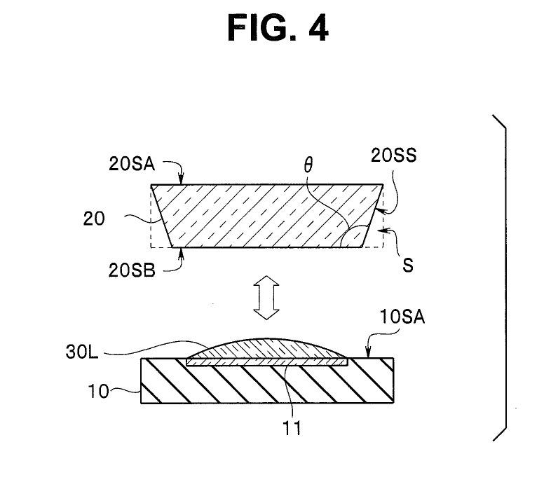

The space S is a space sandwiched between the two surfaces (the light receiving surface 10SA and the side surface 20SS). Thus, liquid resin 30L (see FIG. 4), which has stuck out of the adhesive surface, is housed in the space S under interfacial tension. In other words, the space S houses the excessive resin 30 as a resin pool. Accordingly, the external electrodes 12 (the bumps 13) may not be covered with the resin 30. The external size of the image pickup module 1 may not be increased by the resin 30 expanding toward a side surface of the image pickup device 10.

Further, the image pickup device 10 and the cover glass 20 are made to adhere to each other via not only the adhesive surface but also the fillet. The fillet reinforces the adhesion. Therefore, in the image pickup module 1, the cover glass 20 may not be detached from the image pickup device 10.

The image pickup module 1 is easy to manufacture and high in reliability, as described above.

### <Method for Manufacturing Image Pickup Module>

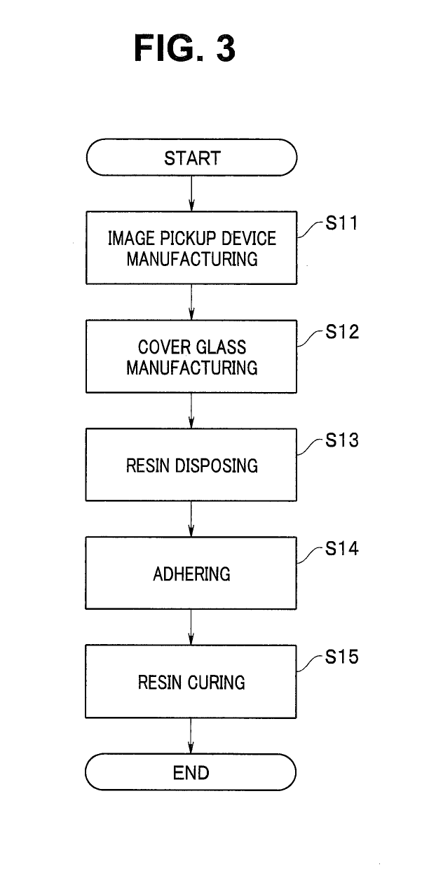

A method for manufacturing the image pickup module 1 will be described below with reference to a flowchart of FIG. 3.

### <Step S11> Image Pickup Device Manufacturing Step

An image pickup wafer including a plurality of light receiving sections and the like is manufactured using a technique for manufacturing a semiconductor on a light receiving surface 10SA in a semiconductor wafer composed of silicon or the like. The image pickup wafer is divided into pieces each serving as an image pickup device 10 by cutting. The image pickup device 10 includes a light receiving section 11 composed of a CMOS image sensor or a CCD and a plurality of external electrodes 12 connected to the light receiving section 11. Note that a semiconductor circuit such as a signal processing circuit may be faulted in addition to the light receiving section 11 in the image pickup device 10.

### <Step S12> Optical Member Manufacturing Step

A glass wafer is cut into a plurality of cover glasses 20. At this time, when the glass wafer is cut using a dicing blade having a V-shaped cross section, a cover glass 20 in which a side surface 20SS is inclined is manufactured. That is, the cover glass 20 is processed such that a second main surface 20SB becomes smaller than a first main surface 20SA simultaneously with the cutting by cutting processing using the dicing blade.

That is, an angle of inclination θ of the side surface 20SS is defined to a desired angle by selecting the dicing blade. The angle of inclination θ is preferably 135°±20° (not less than 115° nor more than 155°), and resin 30 is easily housed in a space S to be a resin pool under interfacial tension if the angle of inclination θ is within the above-described range. Note that the thickness of the cover glass 20 is determined depending on a specification of the cover glass 20, and is not particularly limited.

To process the cover glass 20 such that the second main surface 20SB becomes smaller than the first main surface 20SA, step-cut dicing using two types of dicing which differ in width or etching may be used.

It is needless to say that step S11 may be performed after step S12.

### <Step S13> Resin Disposing Step

Uncured liquid resin 30L is disposed between the light receiving surface 10SA in the image pickup device 10 and the second main surface 20SB in the cover glass 20. For example, the uncured resin 30L is disposed in the light receiving section 11 on the light receiving surface 10SA in the image pickup device 10 using a dispenser or an ink jet method as illustrated in FIG. 4. The resin 30L is epoxy-based, acrylic-based, or silicone-based transparent ultraviolet curable resin, for example. Note that the resin 30L may be a flexible film or thermosetting resin.

The resin 30L may be disposed on the second main surface 20SB in the cover glass 20, or may be disposed on the light receiving section 11 in the image pickup device 10 and the second main surface 20SB in the cover glass 20. That is, the resin 30L is disposed on at least one of the light receiving section 11 and the second main surface 20SB in the cover glass 20.

### <Step S14> Adhering Step

When the light receiving surface 10SA in the image pickup device 10 and the second main surface 20SB in the cover glass 20 are spaced at a predetermined distance apart from each other, the excessive resin 30L sticks out into the space S from the adhesive surface to form a fillet.

For example, the image pickup device 10 is arranged on a stage, and the cover glass 20 is attached to a jig which is movable in XYZ directions. After positioning in the XY directions is performed, when the cover glass 20 moves in the Z-direction, the excessive resin 30 sticks out of the adhesive surface.

### <Step S15> Ultraviolet Light Irradiating Step (Resin Curing Step)

For example, ultraviolet light (UV) is irradiated from the first main surface 20SA in the cover glass 20 via a light guide. Consequently, the resin 30L is cured to become the resin 30 which makes the cover glass 20 and the image pickup device 10 adhere to each other.

In a conventional method, liquid resin may stick out of an adhesive surface between a cover glass and an image pickup device to cover an external electrode. Consequently, the external electrode and a wiring board or the like may not be easily bonded to each other, or a bonding reliability may be reduced. When the resin expands toward a side surface of the image pickup device, the external size of an image pickup module is increased. Accordingly, the resin needs to be rubbed off before being cured, or needs to be ground after being cured. Further, if an adhesive strength is not sufficient, the cover glass may be detached from the image pickup device.

In the manufacturing method according to the present embodiment, the resin 30, which has stuck out, is housed in the space S formed by extending the first main surface 20SA in a direction toward an optical axis (O), i.e., a direction toward the second main surface. Thus, external electrodes 12 (bumps 13) may not be covered with the resin 30. The external size of the image pickup module 1 may not be increased by the resin 30 expanding toward a side surface of the image pickup device 10.

Further, it is easy to work the side surface of the cover glass 20 into an inclined surface. Accordingly, the manufacturing method according to the present embodiment is easy, and a highly reliable image pickup module 1 can be manufactured.

### <Modifications to First Embodiment>

Respective image pickup modules 1A to 1H according to modifications to the first embodiment and respective methods for manufacturing the image pickup modules will be described below. The image pickup modules 1A to 1H are similar to the image pickup module 1, and respectively have the same effects as the effect of the image pickup module 1. Accordingly, components having the same function are assigned the same reference numeral, and hence description of the components is not repeated.

### <Modification 1 to First Embodiment>

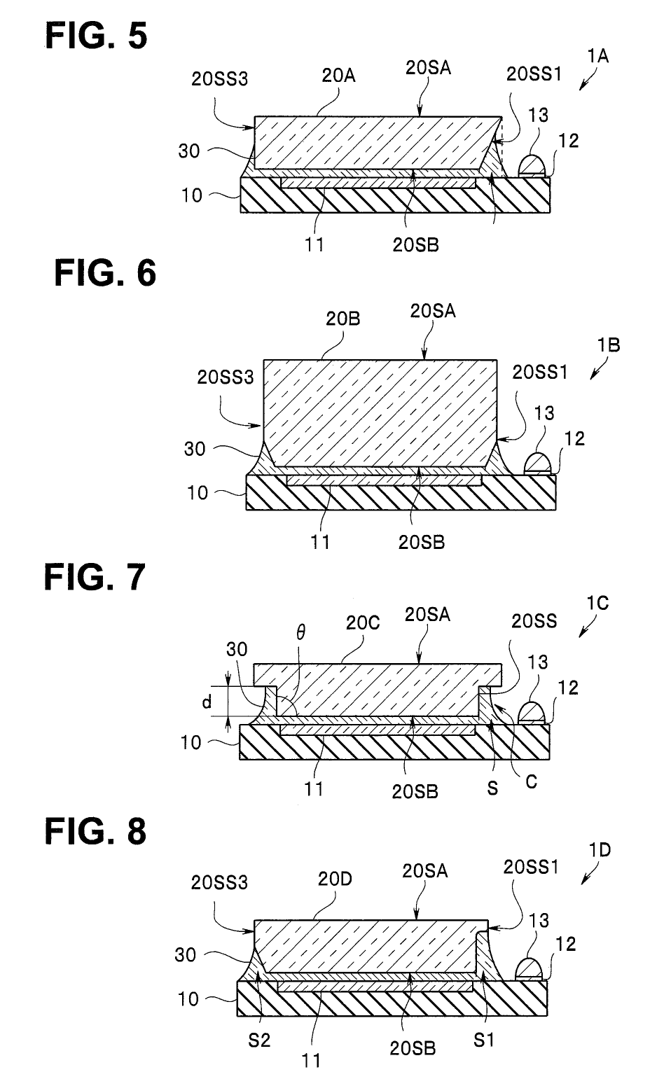

In the image pickup module 1A according to the modification, only one side surface 20SS1 opposing a plurality of external electrodes 12 (bumps 13) among four side surfaces (20SS1 to 20SS4) of a cover glass 20A is an inclined surface which is inclined at an angle of inclination θ obtuse to a second main surface 20SB, and the other three side surfaces (20SS2 to 20SS4) are vertical surfaces perpendicular to the second main surface 20SB, as illustrated in FIG. 5.

That is, if at least the side surface 20SS1 is the inclined surface, the external electrodes 12 (the bumps 13) may not be covered with resin 30.

It is needless to say that in an image pickup module in which a plurality of external electrodes 12 are lined up on both sides with a light receiving section 11 sandwiched therebetween, both side surfaces (20SS1, 20SS3) are respectively preferably inclined surfaces.

### <Modification 2 to First Embodiment>

In a cover glass 20B in the image pickup module 1B according to the modification, only a lower part of a side surface 20SS (on the side of an image pickup device) is an inclined surface, as illustrated in FIG. 6.

If the thickness of the cover glass 20B is large, when the entire side surface is inclined at a predetermined angle θ, and a second main surface 20SB is set to cover a light receiving section 11, a first main surface 20SA may become larger than a light receiving surface 10SA. Further, a side surface 20SS1 in the cover glass 20B protrudes into an area above the external electrode 12 so that the cover glass 20 is not easily bonded to the external electrode 12.

In the image pickup module 1B, even if the thickness of the cover glass 20B is large, the first main surface 20SA does not become large. Thus, the external size of a surface perpendicular to an optical axis is small.

Even if the thickness of the cover glass is 600 μm, for example, when only the lower part of the side surface is inclined, the first main surface 20SA does not become large even if the angle of inclination θ is 135°, for example.

### <Modification 3 to First Embodiment>

A cover glass 20C in the image pickup module 1C according to the modification includes a cutout C in an outer peripheral portion of a second main surface 20SB, as illustrated in FIG. 7. The second main surface 20SB is smaller than a first main surface 20SA due to the cutout C.

Resin 30, which has stuck out into the cutout C serving as a space S formed by extending the first main surface 20SA in a direction toward an optical axis (a direction toward the second main surface), forms a fillet between an image pickup device 10 and the cover glass 20C.

Note that a depth d of the cutout C is preferably 30 μm or less, and is preferably 10 μm or less in particular. If the depth d is within the above-described range, liquid resin 30L is easily housed in the space S under surface tension.

Note that the cutout C is formed by etching or step-cut dicing, for example. Although a side surface of the cutout C is a vertical surface which is inclined at an angle of inclination θ of 90° to the second main surface 20SB, the angle of inclination θ may be an obtuse angle or an acute angle.

Note that the cover glass 20B in the image pickup module 1B already described can be represented as including a cutout an angle of inclination of which is an obtuse angle on the lower part of the side surface (on the side of the image pickup device).

### <Modification 4 to First Embodiment>

In a cover glass 20D in the image pickup module 1D according to the modification, a side surface 20SS1 and a side surface 20SS3 differ in shape, as illustrated in FIG. 8.

That is, the volume of a resin pool (a space S1) formed by the side surface 20SS1 is set larger than a space S2 formed by the other side surface, e.g., the side surface 20SS3 such that resin 30, which has stuck out of the side surface 20SS1, does not cover an external electrode 12 (a bump 13).

That is, four side surfaces of the cover glass need not be the same in shape.

### <Modification 5 to First Embodiment>

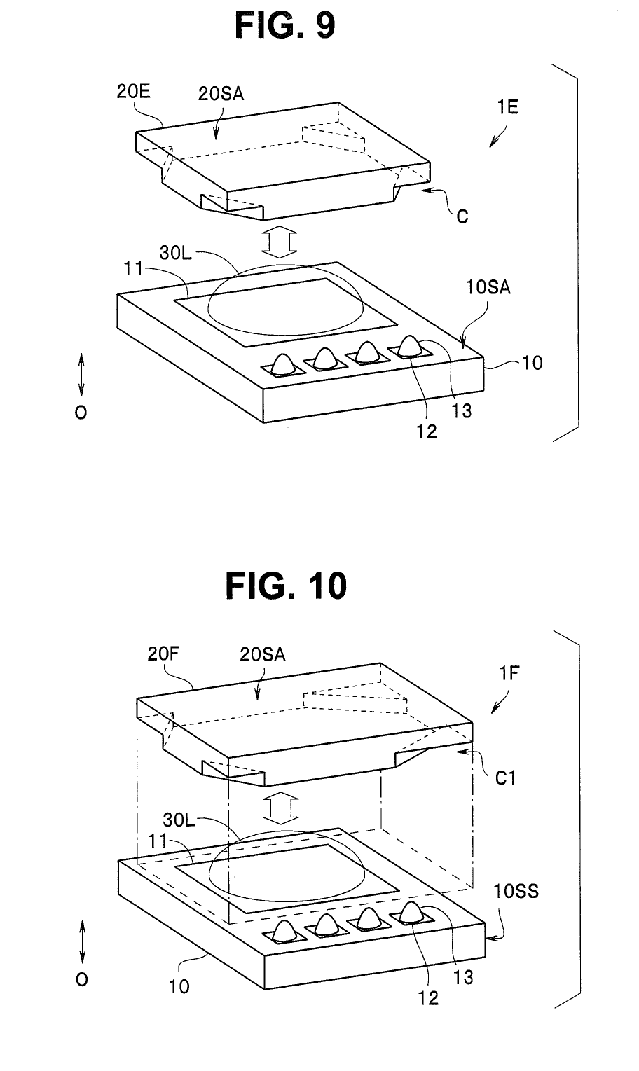

In a cover glass 20E in the image pickup module 1E according to the modification, a second main surface 20SB is smaller than a first main surface 20SA due to respective cutouts C in four corner portions of the second main surface 20SB, as illustrated in FIG. 9.

Resin 30L forms a fillet in each of the cutouts C in the corner portions. The cover glass 20E may not be detached from an image pickup device 10 because each of the corner portions to be easily starting points of the detachment is reinforced by the fillet.

Note that in the cover glass, a side surface 20SS may be an inclined surface, and a cutout may be formed in the corner portion.

### <Modification 6 to First Embodiment>

A cover glass 20F in the image pickup module 1F according to the modification has a planar-view size (a main-surface size) larger than the size of a light receiving surface 10SA in an image pickup device 10, as illustrated in FIG. 10.

In the image pickup module 1F, a planar-view size of the light receiving surface 10SA is as ultra-small as 2.0 mm×1.8 mm, for example. To make the image pickup module smaller in size, the planar-view size of the cover glass 20F is preferably smaller than the size of the light receiving surface 10SA in the image pickup device 10. However, the cover glass 20F has a planar-view size set to 2.2 mm×1.5 mm, for example, to reliably cover a light receiving section 11.

Resin 30L of a cutout C1 in the cover glass 20F forms a fillet not only on the light receiving surface 10SA but also on a side surface 10SS in the image pickup device 10. A portion, which protrudes from the light receiving surface 10SA, of the cover glass 20F may tend to be a starting point of detachment. However, the portion is reinforced by the fillet in the image pickup module 1F. Therefore, the cover glass 20F may not be detached from the image pickup device 10.

### <Modification 7 to First Embodiment>

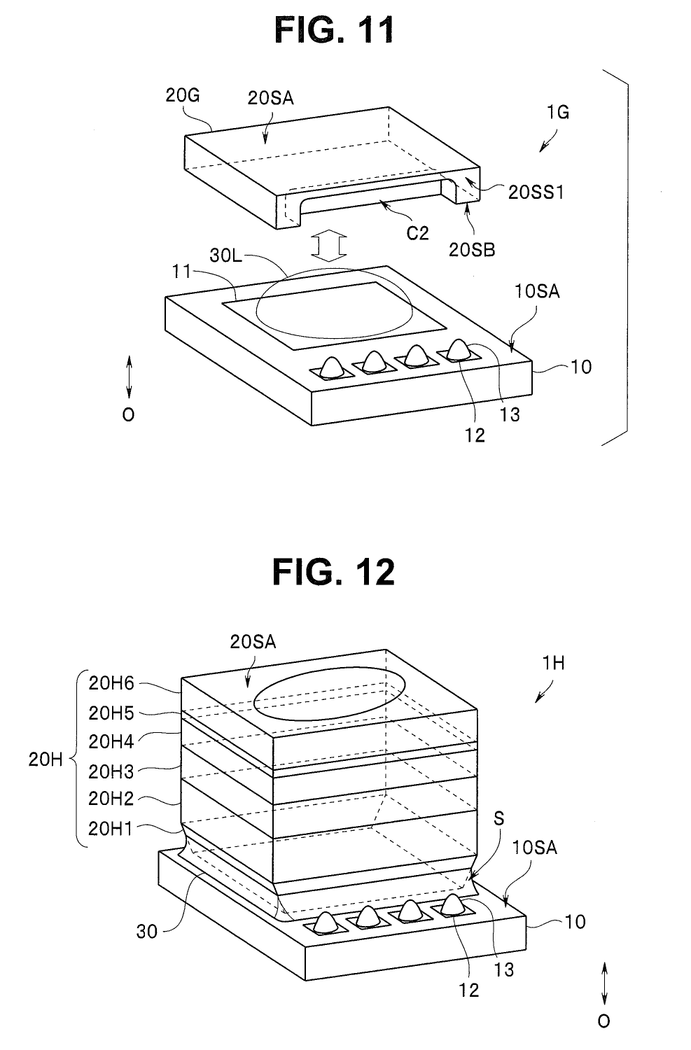

A cover glass 20G in the image pickup module 1G according to the modification includes a cutout C2 in a part of a first side surface 20SS1, as illustrated in FIG. 11.

That is, the cutout C2 may be formed in only a part of one side surface 20SS1.

### <Modification 8 to First Embodiment>

In the image pickup module 1H according to the modification, an optical member is a lens unit 20H, as illustrated in FIG. 12.

The lens unit 20H is a wafer level optical system in which a plurality of optical members 20H1 to 20H6 such as a cover glass 20H1, lenses 20H3 and 20H6, an aperture 20H5, and optical path length adjustment members 20H4 and 20H2 are stacked.

When a lens wafer including a plurality of lenses, an aperture wafer including a plurality of apertures, an optical path length adjustment wafer including a plurality of optical paths (through holes), and a bonding wafer to which a glass wafer is bonded are cut, the lens unit 20H is manufactured.

In the lens unit 20H, a side surface of the cover glass 20H1 becomes an inclined surface, to constitute a space S serving as a resin pool. Of course, a side surface of the optical path length adjustment member 20H2 may also be an inclined surface, for example.

That is, the optical member is not limited to the cover glass. The optical member may be the wafer level optical system in which a plurality of optical members 20H1 to 20H6 are stacked.

### Second Embodiment

An image pickup module 1I according to a second embodiment and a method for manufacturing the image pickup module 1I will be described below. The image pickup module 1I is similar to the image pickup module 1, and has the same effect as the effect of the image pickup module 1. Accordingly, components having the same function are assigned the same reference numeral, and hence description thereof is not repeated.

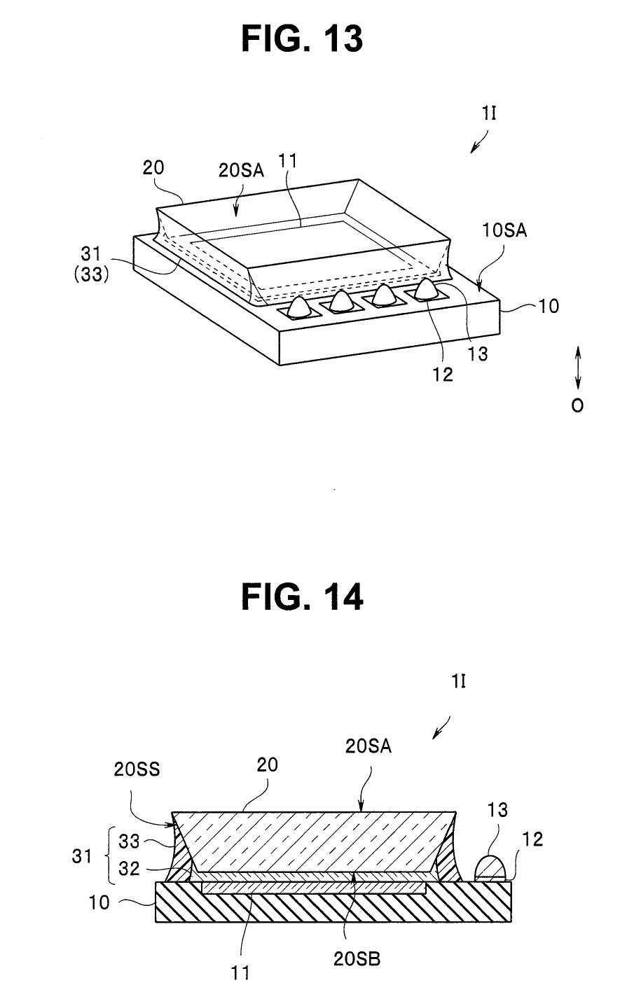

In the image pickup module 1I, resin 31 includes transparent first resin 32 disposed between a light receiving section 11 and a cover glass 20 and second resin 33 having a light shielding property disposed around the first resin 32, as illustrated in FIG. 13 and FIG. 14.

A side surface 20SS is covered with the second resin 33 having a light shielding property. Thus, the image pickup module 1I is not easily affected by outside light. The second resin 33 may be the same as or different from the first resin 32. From the viewpoint of productivity and reliability, the second resin 33 is preferably the first resin 32 including a pigment having a light shielding property such as carbon.

A side surface of the cover glass 20 in the image pickup module 1I is an inclined surface, like in the image pickup module 1. However, it is needless to say that the image pickup modules 1A to 1H in which a configuration of a cover glass differs from the configuration of the cover glass 20 respectively have the same effects as the effect of the image pickup module 1I when the resin 30 is caused to have the same configuration as the configuration of the resin 31.

### Third Embodiment

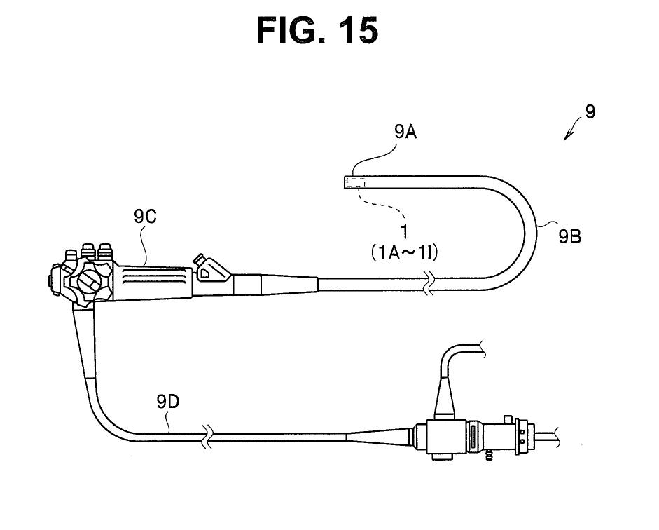

An endoscope 9 according to a third embodiment will be described below. The endoscope 9 includes an insertion section 9B in which an image pickup module 1 (1A to 1I) being easy to manufacture and small in size is disposed in a distal end portion 9A, an operation section 9C disposed at a proximal end side of the insertion section 9B, and a universal code 9D extending from the operation section 9C, as illustrated in FIG. 15. The universal code 9D is connected to a wiring board (not illustrated) bonded to bumps 13 in the image pickup module 1.

The endoscope 9 has a small diameter, has a high property, and is easy to manufacture because the image pickup module 1 (1A to 1I) being small in size and having a high property is provided in the distal end portion 9A of the insertion section 9B. Note that the endoscope 9 may be a rigid endoscope, although a flexible endoscope. The endoscope according to the present embodiment may be of a capsule type or may be for medical use or industrial use if the endoscope includes the image pickup module 1 (1A to 1I).

The present invention is not limited to the above-described embodiments and modifications, and can be subjected to various changes and alterations without departing from the spirit of the present invention.

What is claimed is:

1. An image pickup module comprising:
an image pickup device including a light receiving section and an external electrode on a light receiving surface on which an image pickup optical system including an optical axis forms an object image; and
an optical member including a first main surface and a second main surface opposing the first main surface, the second main surface being made to adhere to the light receiving surface via resin, and covering the light receiving section and not covering the external electrode,
wherein in the optical member, the second main surface is smaller than the first main surface, and the resin sticks out into a space formed by extending the first main surface in a direction toward the second main surface on the optical axis, to form a fillet between the image pickup device and the optical member.

2. The image pickup module according to claim 1, wherein
a side surface of the optical member is inclined with respect to the second main surface.

3. The image pickup module according to claim 1, wherein
a cutout is provided in an outer peripheral portion of the second main surface of the optical member.

4. The image pickup module according to claim 1, wherein
the second main surface at a corner portion of the optical member is smaller than the first main surface.

5. The image pickup module according to claim 1, wherein
the resin includes transparent first resin disposed between the light receiving section and the optical member and second resin having a light shielding property disposed around the first resin.

6. An endoscope comprising the image pickup module according to claim 1.

7. A method for manufacturing an image pickup module, the method comprising:
a step of manufacturing an image pickup device including a light receiving section and an external electrode on a light receiving surface on which an image pickup optical system including an optical axis forms an object image;
a step of manufacturing an optical member including a first main surface and a second main surface opposing the first main surface by processing the optical member such that the second main surface is smaller than the first main surface;
a step of disposing uncured resin between the light receiving surface of the image pickup device and the second main surface of the optical member;
a step of making the second main surface adhere to the light receiving surface in such a manner that the optical member covers the light receiving section and does not cover the external electrode and the light receiving surface and the second main surface are spaced apart from each other at a predetermined distance, so as to cause the excessive resin to stick out into a space formed by extending the first main surface in a direction toward the second main surface on the optical axis to form a fillet between the image pickup device and the optical member; and
a step of curing the resin.

8. The method for manufacturing the image pickup module according to claim 7, wherein
the optical member manufacturing step is cutting processing using a dicing saw having a V-shaped cross section or step-cut cutting processing using two types of dicing saws which differ in width.
